(19) United States
(12) Patent Application Publication
(10) Pub. No.: US 2017/0301567 A9
(43) Pub. Date: Oct. 19, 2017

(54) SYSTEM OF CONTROLLING TREATMENT LIQUID DISPENSE FOR SPINNING SUBSTRATES

(71) Applicant: TOKYO ELECTRON LIMITED, TOKYO (JP)

(72) Inventor: IAN J BROWN, AUSTIN, TX (US)

(21) Appl. No.: 14/085,720

(22) Filed: Nov. 20, 2013

Related U.S. Application Data
(60) Provisional application No. 61/728,359, filed on Nov. 20, 2012.

(51) Int. Cl. H01L 21/67

(52) U.S. Cl. CPC H01L 21/67051; H01L 21/67115

(57) ABSTRACT

Provided is a method for cleaning an ion implanted resist layer or a substrate after an ashing process. A duty cycle for turning on and turning off flows of a treatment liquid in two or more nozzles is generated. The substrate is exposed to the treatment liquid comprising a first treatment chemical, the first treatment chemical with a first film thickness, temperature, total flow rate, and first composition. A portion of a surface of the substrate is concurrently irradiated with UV light while controlling the selected plurality of cleaning operating variables in order to achieve the two or more cleaning objectives. The cleaning operating variables comprise two or more of the first temperature, first composition, first film thickness, UV wavelength, UV power, first process time, first rotation speed, duty cycle, and percentage of residue removal.

Pursuant to 37 C.F.R. §1.78(a)(4), this application claims the benefit of and priority to prior filed co-pending Provisional Application Ser. No. 61/728,359, entitled “METHOD OF CONTROLLING TREATMENT LIQUID DISPENSE FOR SPINNING SUBSTRATES”, filed on Nov. 20, 2012, which is expressly incorporated herein by reference.

### FIELD

The present application generally relates to semiconductor processing and specifically to a cleaning process on a substrate using a first step of immersion in a first treatment chemical and concurrently irradiating the substrate with ultra-violet (UV) light and a second step using a wet clean process using a second treatment chemical.

### RELATED ART

In semiconductor processing, control of generation and lifetime of active chemical species is important to optimize cleaning processes with respect to removal efficiency of desired material, process time, and selectivity to other materials present on the substrate. In aqueous and plasma chemistry, generation of radicals is a convenient way to generate highly reactive and targeted species to remove material. Radicals are generated by mixing of two or more chemicals, (e.g. sulfuric acid and hydrogen peroxide to form hydroxyl radicals) or by application of energy, for example, light, heat, electrical/magnetic force, electrochemical, or mechanical energy. Ion implanted photoresist is challenging to remove because a hard crust layer forms during the implant process on the photoresist. When a certain range of doses and energies are used to implant ions on the resist, these hard crust layers have to be removed using a plasma ashing step. There are two methods known to remove ion implanted resist at levels of 1e¹⁵ atoms/cm² and higher. The first method is a two-step process using oxidizing/reducing plasma ash and a 120-140° C. sulfuric and peroxide mixture (SPM) wet process to remove residual organics. The challenge with this process is oxidization of the silicon substrate leading to loss of dopant in subsequent wet cleans. The second method is an all wet removal approach using SPM chemistry.

The challenge with all wet process removal or wet benches is that the SPM has to be heated to temperatures approaching 250° C. to achieve the desired resist removal performance and at a removal rate that is practical for manufacturing. Wet benches typically operate with SPM temperatures up to 140° C. To reach SPM temperatures of 250° C., one-pass single substrate process tools are required. However, over time, the SPM loses its activity as the sulfuric acid is diluted by the continuous replenishment of hydrogen peroxide that is required to retain its cleaning activity. With SPM, the best cleaning performance is achieved above 100 wt % total acid in the SPM. SPM below 80 wt % total acid has very poor cleaning performance and a fresh batch of 108-96 wt % sulfuric acid is often used. Methods exist to remove the excess water from the recycled SPM or using electrolyzed sulfuric acid to extend the usage life of the sulfuric acid. Both methods significantly increase the complexity, capital cost, and operating costs of the resist strip process. Similar considerations are also applicable to cleaning of substrates after an ashing process.

Later approaches include cleaning techniques using a two-step process with hydrogen peroxide and ultra violet (UV) light followed by a wet stripping process. One such technique is U.S. Patent Publication No. 2012/0052687, by Raghaven, et al.,(Raghaven), “Use of Catalyzed Hydrogen Peroxide (CHP) Chemical System for Stripping of Implanted State-of-the-Art UV Resists”, filed on Dec. 29, 2010, where a catalyzed hydrogen peroxide solution is used with UV light to disrupt the crust of implanted photoresist and subsequently removing the underlying photoresist with a sulfuric acid peroxide mixture (SPM) in a wet etch process. Effectiveness of this technique is limited by the specific ranges of concentration of the catalyzed hydrogen peroxide, temperature of the treatment liquids, and speed of rotation of the substrate.

Another technique is contained in U.S. application Ser. No. 13/670,381, by Brown, I J, “METHOD OF STRIPPING PHOTORESIST ON A SINGLE SUBSTRATE SYSTEM”, filed on Nov. 6, 2012 (Brown). Brown introduced operating variables consisting of UV wavelength, UV power, first rotation speed, first flow rate, second process time, second rotation speed, percentage of residue removal, and dispense temperature. The additional operating variables provide some flexibility to control the cleaning process, but some issues develop as the process is used in a manufacturing environment. Some of the issues include: a) rotation of bigger size substrates require new and stronger motors and associated housing, b) time constraints involved in starting up and stopping rotation of substrate increases with increasing size and speed, c) time needed to perform the softening of the residue is a function of at least two or more operating variables such as thickness of the first chemical film, rotation speed of the substrate, and exposure time to the UV light, concentration of the first chemical, and intensity of the UV light. The position of the nozzle relative to the substrate and flow rate of the first chemical also affects the cleaning of the substrate. In order to make single substrate cleaning of substrates economically feasible, these issues and operating challenges must be addressed when the cleaning process is implemented in production volume environment.

The amount of treatment liquid used in cleaning systems is cost item that requires attention as more cleaning systems switch to single substrate systems. The challenge with reducing the amount of treatment liquid used is that the substrate needs to be wet all throughout during the process, that is, no dry spots as these causes some of residue or irregularity in the end product. Efforts to reduce the amount of treatment liquid used must be considered at the same time as ensuring the substrate is always wet. Another factor that requires attention is that with the advent of larger substrates, the temperature from the center to the edge of the substrate may drop to an extent that the reaction between the treatment liquid and the substrate at the edge is not the same as it is close to the center. All of these considerations need to be optimized concurrently to ensure the absolute wetting of the substrate, maintain a temperature gradient on the treatment liquid within an acceptable range, and use the least amount of treatment liquid. In addition, there is a need for a stripping method and system that makes single substrate process tools competitive in terms of cost of ownership and higher reliability in addition to expanding the process window for the stripping an ion implanted resist or cleaning or performing a post-ash cleaning.

### SUMMARY

Provided is a method for cleaning an ion implanted resist layer or a substrate after an ashing process. A duty cycle for turning on and turning off flows of a treatment liquid in two or more nozzles is generated. The substrate is exposed to the treatment liquid comprising a first treatment chemical, the first treatment chemical with a first film thickness, temperature, total flow rate, and first composition. A portion of a surface of the substrate is concurrently irradiated with UV light while controlling the selected plurality of cleaning operating variables in order to achieve the two or more cleaning objectives. The cleaning operating variables comprise two or more of the first temperature, first composition, first film thickness, UV wavelength, UV power, first process time, first rotation speed, duty cycle, and percentage of residue removal. Two or more cleaning operating variables are optimized to achieve the two or more cleaning objectives comprising at least two of: (1) complete wetting of the surface of the substrate, (2) minimum amount of treatment liquid used, and (3) a target temperature profile of treatment liquid from center to edge of the substrate.

### LIST OF FIGURES

FIG. 1A depicts an exemplary prior art architectural diagram of the profile of a structure with crust fused to the substrate surface and near the edge bead region;

FIG. 1B depicts an exemplary prior art graph of relative strip rate as a function of temperature of the resist versus the carbonized layer. Refer to Butterbaugh Presentation on “ASH-FREE, WET STRIPPING OF HEAVILY IMPLANTED PHOTORESIST”, FSI International, Surface Preparation and Cleaning Conference, Austin, Tex., on May 4, 2006;

FIG. 2 depicts an exemplary prior art architectural diagram of a single substrate implementation of the first step of a UV peroxide process for stripping an ion implant resist layer;

FIG. 3 depicts an exemplary architectural diagram of the two-step UV-peroxide (UVP) and sulfuric peroxide mixture (SPM) processes in an exemplary embodiment of the present invention;

FIG. 4A depicts an exemplary top-view of an area of a substrate prior to cleaning while FIG. 4B depicts an exemplary side-view of a portion of substrate prior to cleaning;

FIG. 5A depicts another exemplary top-view of an area of a substrate before cleaning while FIG. 5B is another exemplary top view of the cleaned substrate;

FIG. 6 is an exemplary schematic diagram of a cleaning system in an embodiment of the present invention;

FIG. 7 is an exemplary schematic diagram of stacks of rSPM and stacks UVP and stacks of UVP and RSPM in one embodiment of the present invention;

FIG. 8 is an exemplary method flowchart of an embodiment of the present invention;

FIG. 9 is an exemplary flowchart of adjusting one or more treatment operating variables to meet the two or more objectives of the present invention; and

FIG. 10 is an exemplary architectural diagram of a single substrate resist treatment system in an embodiment of the invention utilizing optical and process metrology tools.

### DETAILED DESCRIPTION OF EXEMPLARY EMBODIMENTS

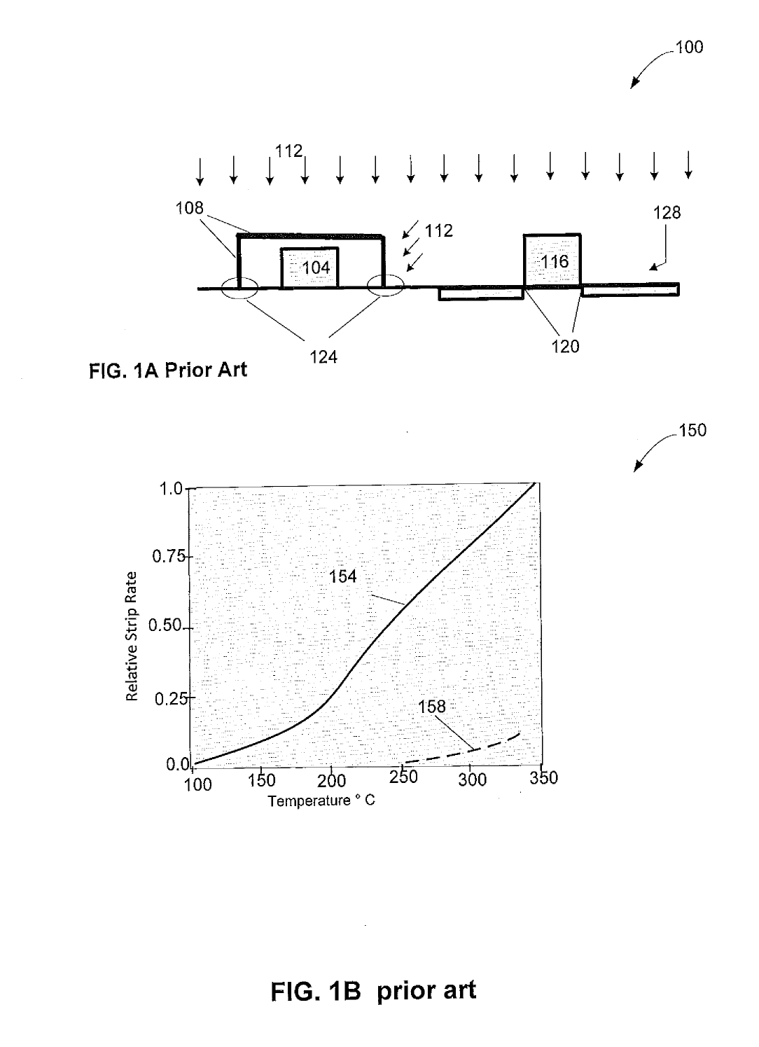

FIG. 1A depicts an exemplary prior art architectural diagram 100 of the profile of a structure with a crust 108 fused to the surface, points 124, of a structure 104 in the substrate 128 and profile of an adjoining structure 116 without crust fused to the surface, points 120. The high dose ions 112 used in a previous process can cause development of the crust 108 that makes cleaning difficult. Formation of the crust 108 can be at the surface, points 124, of structure 104 in substrate 128 or near the edge bead region (not shown) of the substrate 128. Resist strip performance depends on the ion implant dose and energy. Effectiveness of a resist strip performance is correlated to the extent of removal percentage of the resist, speed of the process, and cost of ownership, which shall be discussed below. FIG. 1B depicts exemplary prior art graphs 150 of relative strip rate as a function of temperature of the resist compared to the temperature of the carbonized layer, such the crust 108 in FIG. 1A. The relative strip rate graph 154 for the resist has a greater up-slope as the temperature goes from 100° C. to 350° C. ending at 1.00 relative strip rate compared to the relative strip rate graph 158 of the carbonized layer at less than 0.20 relative strip rate at 340° C. Furthermore, the energy used in stripping the resist was much less, Eₐ=0.17 ev, compared to the energy used in stripping the carbonized layer, Eₐ=2.60 ev, with the carbonized layer having a much lower relative strip rate.

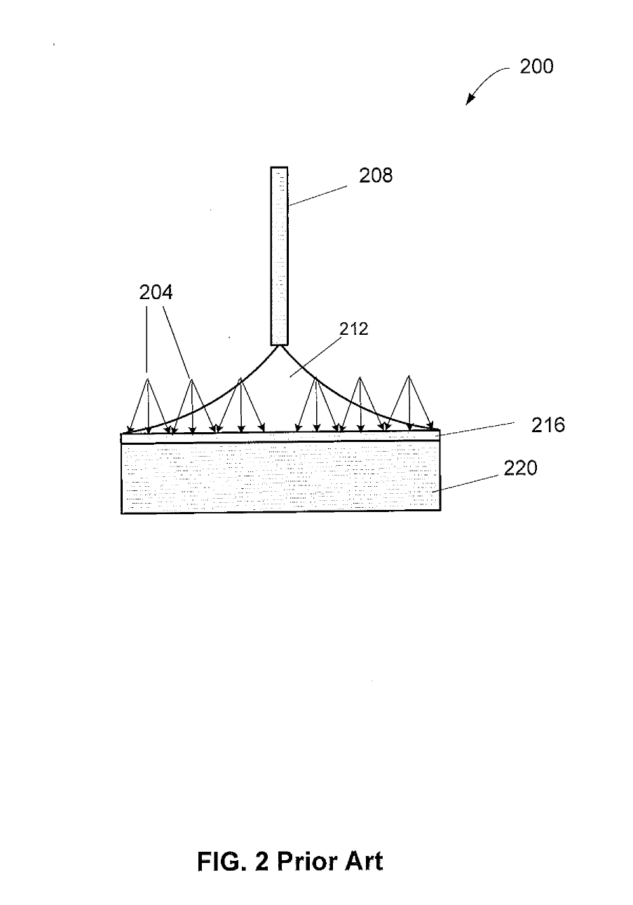

FIG. 2 depicts an exemplary prior art architectural diagram 200 of a single substrate implementation of the first step of a UV peroxide process for stripping an ion implant resist layer. A dispense nozzle 208 is used to dispense hydrogen peroxide solution 212 onto a rotating substrate 220 where the substrate 220 has an ion implant resist layer 216 and the substrate 220 was immersed in the hydrogen peroxide solution 212. The UV lamp 204 directs the irradiation concurrently on the hydrogen peroxide solution 212. The second step comprises the use of a sulfuric peroxide mixture (SPM) to further remove the rest of the resist layer 216 not removed in the first step. Current art cleaning techniques generally use 254 nm UV lamps, the hydrogen peroxide solution 212 at 1 to 30 wt % at 25 to 60° C., and the SPM with a ratio of 2:1 sulfuric acid to hydrogen peroxide. The highest resist strip performance for current art was obtained with 5 wt % hydrogen peroxide solution in the first step and total of 15 minutes to complete the first and second steps.

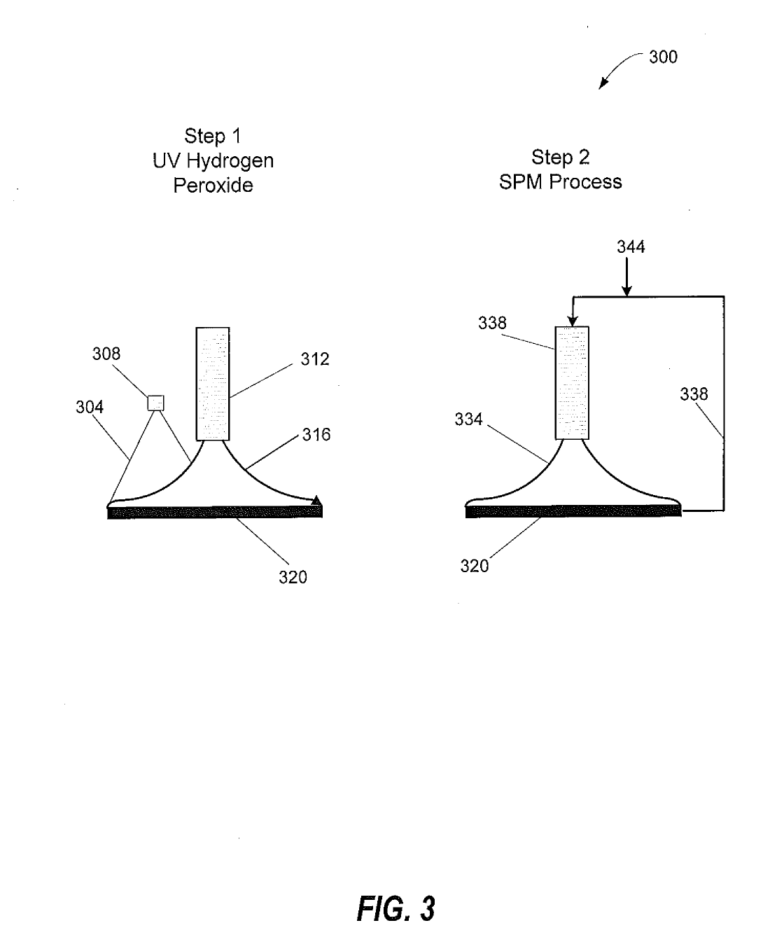

FIG. 3 depicts an exemplary architectural diagram 300 of the two-step UV-peroxide (UVP) and sulfuric peroxide mixture (SPM) processes in an exemplary embodiment of the present invention. In Step 1 (first step), a substrate 320 having a resist layer is positioned in a processing chamber (not shown), the substrate rotating at a first rotation speed of 300 to 12,000 rpm, is immersed in 10 wt % H₂O₂, 316, from one or more nozzles 312. The immersed substrate 320 is concurrently irradiated with one or more UV lamps 308 where the UV light 304 generated is 254 nm. In the Step 2 (second step), a nozzle 338 is used to dispense SPM 334 having a ratio of about 20:1 of sulfuric acid to hydrogen peroxide where the SPM 334 is dispensed onto the substrate 320 at about 150° C., and the substrate 320 is in a second rotation speed of from 300 to 1,000 rpm. The SPM 334 can optionally be recirculated with a recycle subsystem 338 where new hydrogen peroxide can be introduced to maintain a target ratio of the sulfuric acid to hydrogen peroxide, at point 344.

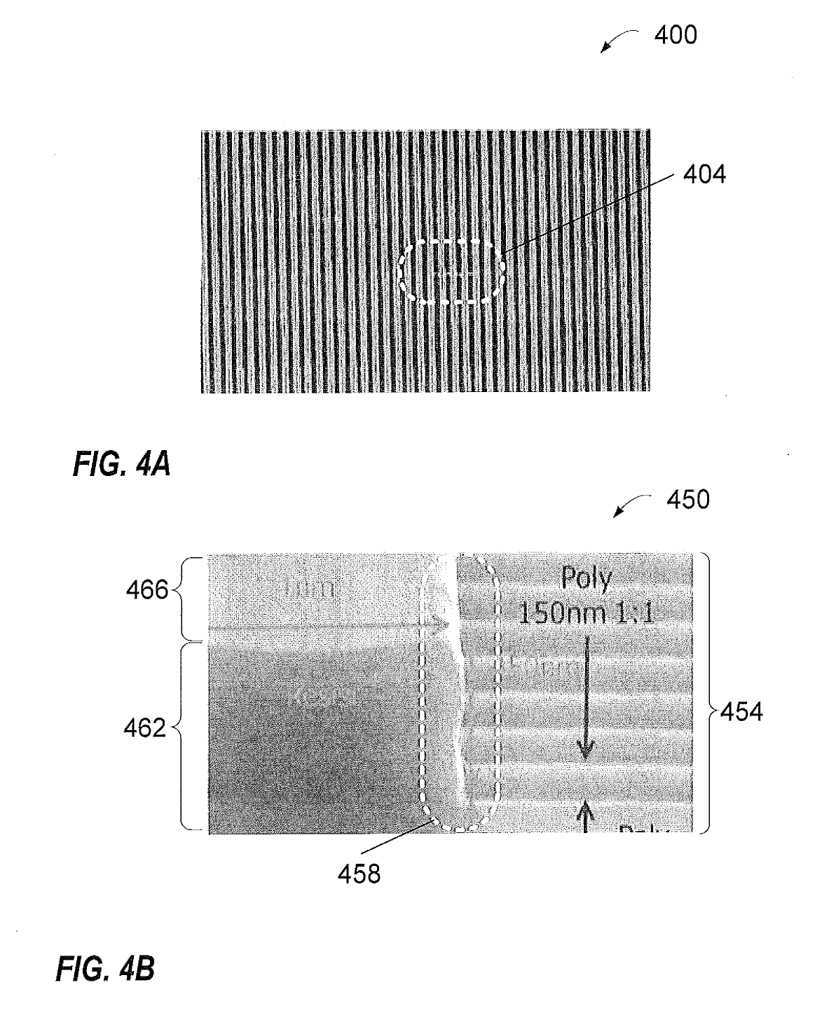

FIG. 4A depicts an exemplary top-view 400 of an area of a substrate prior to cleaning while FIG. 4B depicts an exemplary side-view 450 of a portion of substrate prior to cleaning. FIG. 4A shows the residue enclosed in the white dotted line 404 in between the lines and spaces of a grating for cleaning. In FIG. 4B, the side view shows a layer of substrate material 466 above the photoresist 462 and in another portion of the substrate a polymer film 454 is shown. In between the polymer film 454 and the layer of substrate material 466 and the resist 462, residues are also visible in the enclosed area of the white dotted area 458. The object of the cleaning system is to clean the substrate of residue and photoresist 462.

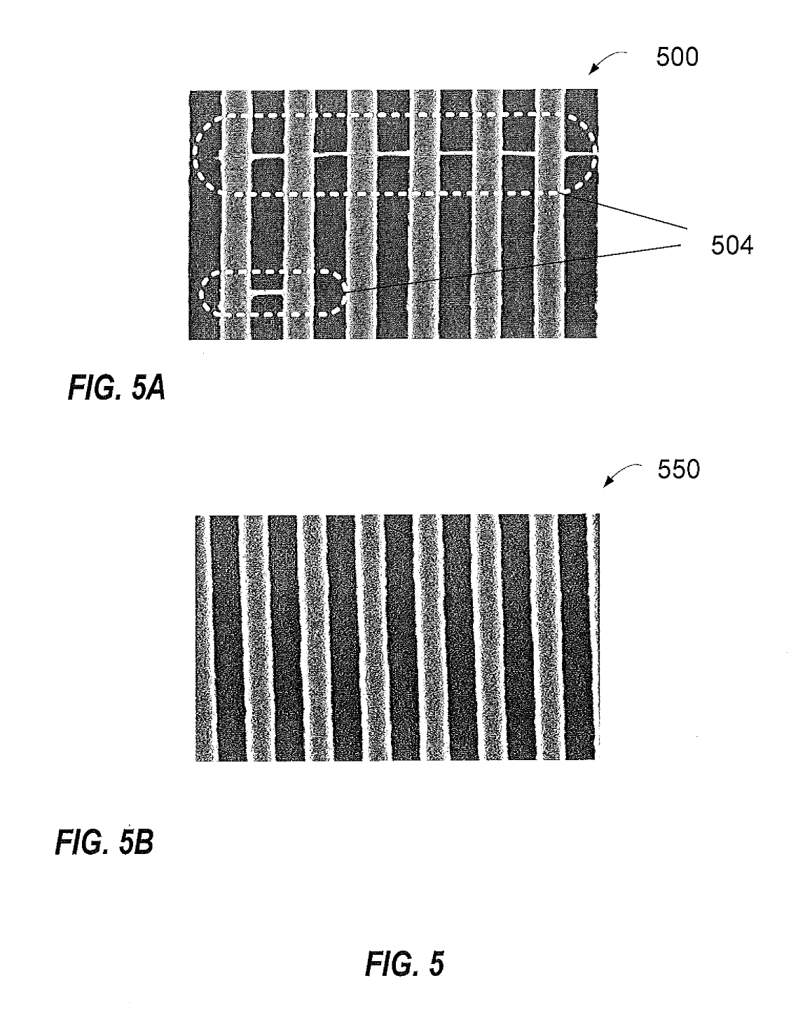

FIG. 5A depicts another exemplary top-view 500 of an area of a substrate before cleaning which shows the residue as a white line in the areas enclosed in the white dotted line while FIG. 5B is another exemplary top view 550 of a cleaned substrate which does not show any presence of residue. As mentioned above, the invention is configured to perform the two-step cleaning operation where the operating variables are concurrently optimized to get absolute wetting of the substrate, maintain a temperature gradient on the treatment liquid within an acceptable range, and use the least amount of treatment liquid.

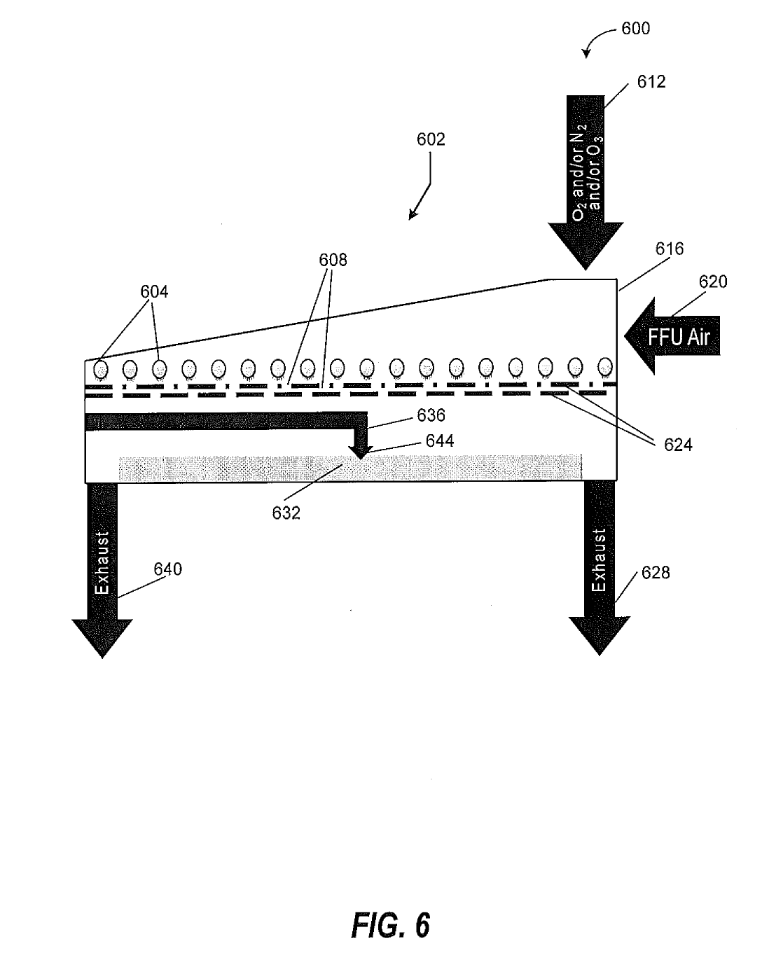

FIG. 6 is an exemplary diagram 600 for a cleaning system 602 where the UV source 604 is located above a diffusion plate 624, the diffusion plate 624 configured to block 185 nm wavelength light to irradiate the substrate 632 during the pre-treatment process and protect the UV source 604 and associated equipment during the subsequent wet clean process. The process gas 612 can comprise oxygen and/or nitrogen. Alternatively, the process gas can comprise oxygen and/or nitrogen and/or ozone. In another embodiment, fan filter unit (FFU) air or CDA 620 can be introduced into the process chamber 616 as the process gas during the pre-treatment process. During the wet clean process, the treatment liquid 644 delivered into the process chamber 616 by delivery device 636 onto the substrate 632, where the treatment liquid 644 and the process gas 612 or 620 are removed through exhaust units 640, 628. The system hardware for the substrate cleaning system is simplified because there is no requirement for an external oxygen or ozone containing oxygen gas feed into the UV chamber. Processing with standard air has demonstrated the ability to generate sufficient ozone and oxygen atoms for the pre-treatment process to work. Feeding oxygen or ozone carrying gas lines increases tool cost because of the associated hardware design safety requirements. The inventor found out that significantly shorter UV exposure times can be realized by the combined pre-treatment process using UV and a process gas followed by a wet clean process. Further, the inventor was also able to shorten the wet clean process time. Moreover, the generation of in-situ process gas also reduces the number of UV sources employed in the design of the substrate cleaning system. For example, all UV hardware in FIG. 6 is contributing directly to the cleaning of the substrate, ultimately to the generation of atomic oxygen.

Referring to FIG. 6, an embodiment of the invention includes an indirect source of ozone generated either by vacuum UV (VUV) sources (<200 nm), corona discharge or UV source with wavelengths below 200 nm fed into the substrate processing chamber while under irradiation with 254 nm only radiation. The absorption of the radiation by the ozone initiates the formation of oxygen atoms at the substrate surface that enable the damage-free cleaning of substrates. Alternatively, in another embodiment, the substrate is irradiated with ozone emitting UV where an 185 nm absorbing filter is placed between the substrate with geometry that prevents direct and indirect illumination with 185 nm but allows a diffusion path for ozone to reach the substrate surface. Mass transport of the process gas can be enhanced by flowing the oxygen filled atmosphere through the <200 nm wavelength absorbing gas diffusion plate.

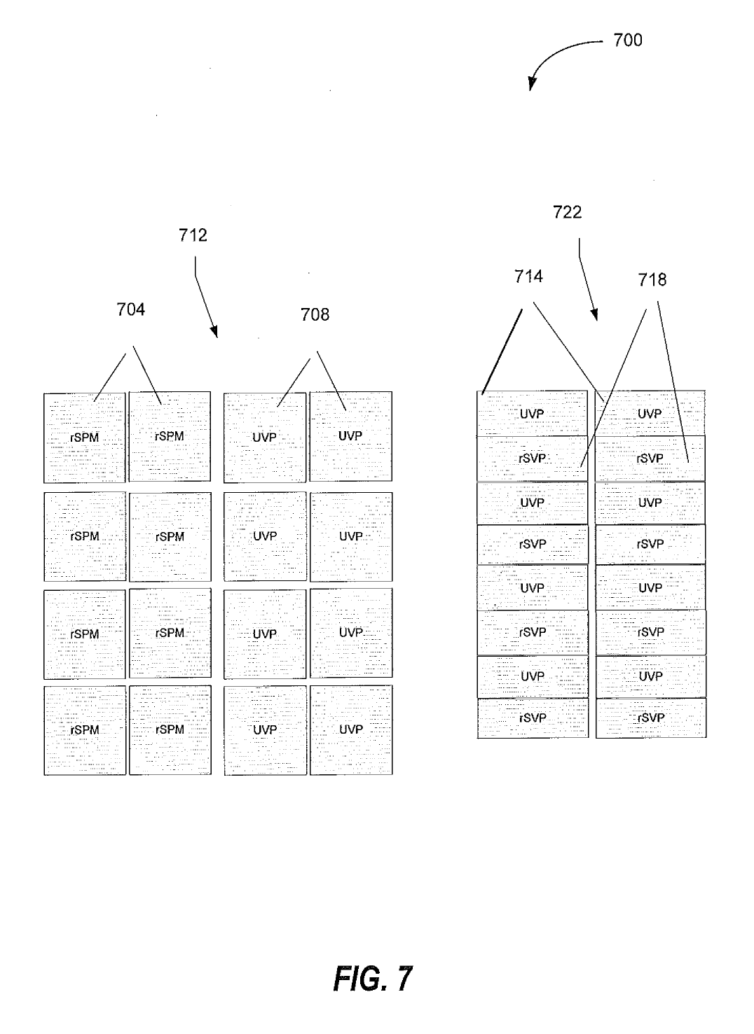

FIG. 7 is an exemplary architectural diagram 700 of a stack of dedicated spin chambers 712 embodiment and an all-in-one spin chamber 722 embodiment of the present invention. The dedicated spin chambers 712 can be one or more stacks of UV-peroxide (UVP) chambers 708 where the substrate (not shown) is loaded, immersed in the hydrogen peroxide solution and concurrently irradiated with one or more UV light devices for a first process time at a first rotation speed of the substrate. Other oxidizers in addition to hydrogen peroxide can also be used. The substrates (not shown) are unloaded from the UVP chambers 708 and loaded onto the recycle SPM (rSPM) processing chamber 704 where the resist is treated with SPM for a second process time at a second rotation speed of the substrate. In another embodiment, the all-in-one spin chambers 722 can be one or more stacks of processing chambers each further comprising a UVP chamber 714 and an rSPM chamber 718. In an embodiment, the UVP chamber 714 and the rSPM chamber 718 can be a single processing chamber having one of more nozzles for dispensing the hydrogen peroxide solution and/or the SPM. Alternatively, different nozzles can be used for dispensing the hydrogen peroxide solution and the SPM. In other embodiments, acids other than sulfuric acid and oxidizers other than hydrogen peroxide can also be used.

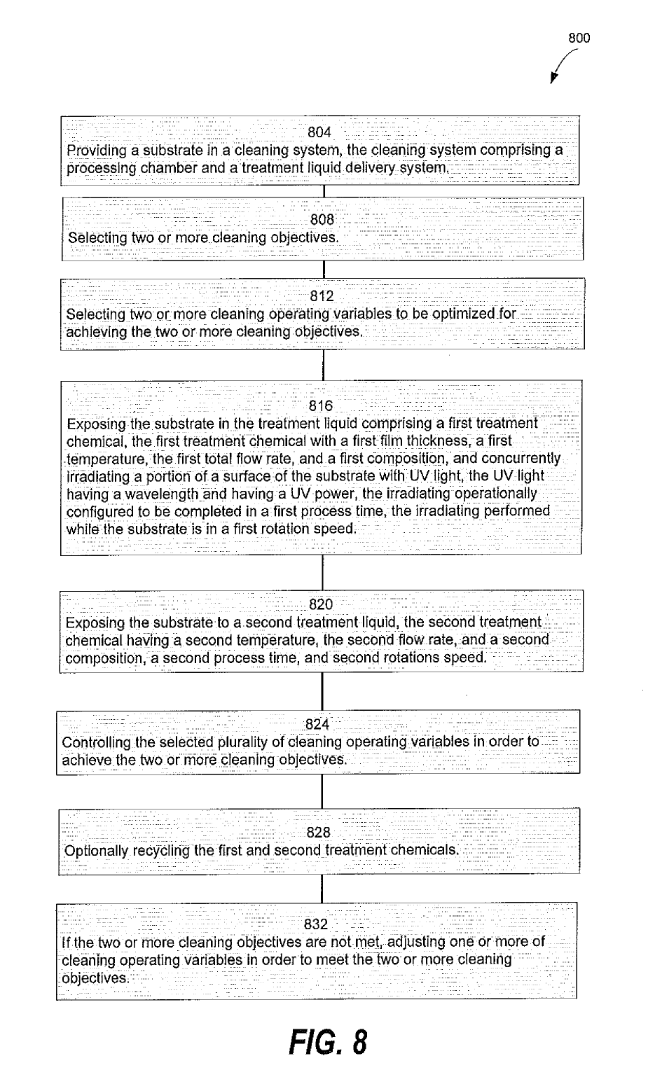

FIG. 8 is an exemplary method flowchart 800 of an embodiment of the present invention. In operation 804, a substrate is provided in a cleaning system comprising a processing chamber and a treatment liquid delivery system. The substrate cleaning may be a post-etch stripping of an ion implanted resist or cleaning or performing a post-ash cleaning. Moreover, the substrate cleaning process include means for performing a standard clean 1 (SC 1), a standard clean 2 (SC 2), water cleaning, or solvent cleaning and/or wherein the substrate cleaning process performed includes a treatment liquid comprising hydrofluoric acid (HF), diluted HF, or buffered HF; or the substrate cleaning process includes a treatment liquid comprising deionized water, isopropyl alcohol, deionized water and ozone, rinsing fluids, sulfuric acid peroxide mixture (SPM), sulfuric acid peroxide and ozone mixture (SOM), phosphoric acid, or phosphoric acid and steam mixture. In an embodiment, treatment liquid is a sulfuric acid peroxide mixture (SPM) or sulfuric acid peroxide and ozone mixture (SOM), the substrate cleaning process is photoresist stripping, the flow rate of the SPM is 2 liters per minute or less, the selected two or more dispense devices comprise 5 nozzles, including a central nozzle and 4 additional nozzles, arranged in a line pattern, and the substrate can be from 200 to 450 mm. All the above cleaning processes are known to people in the art.

With regards to nozzles, the selected two or more dispense devices can have varying sizes of dispense width. In one embodiment, the selected two or more dispense devices are positioned above the substrate according to a selected pattern, the selected pattern including a height from the substrate surface to the dispense device and distance between a central dispense device and each additional dispense device of the selected two or more dispense devices. In another embodiment, the selected two or more dispense devices can comprise a central nozzle and one or more additional nozzles located at selected distances from the central nozzle towards an edge of the substrate, the central nozzle configured with a flow rate lower than any of the one or more additional nozzles. The dispense width of a nozzle requires sufficient size to allow a continuous dispense of the treatment liquid at the selected flow rate of the dispense device. For example, the first delivery device nozzles needs to be configured to support a treatment liquid flow rate in a range from 15 to 500 mL/min, 15 mL/min, or less than 15 mL/min. In still another embodiment, selection and placement, the selected two or more dispense devices comprising of nozzles can be connected to a single supply line and the duty cycle requires sequential turning on and turning off from a central nozzle towards a nozzle closest to the edge of the substrate and from the nozzle closest to the edge of the substrate towards the central nozzle. In yet another embodiment, each dispense device of the selected two or more dispense devices can be independently connected to a supply line and can be turned on and turned off independently; and/or wherein the selected two or more dispense devices are disposed in a line pattern, a cross pattern, a 3-ray star pattern configuration; and/or wherein the selected two or more dispense devices can be turned on and turned off independently.

In operation 808, two or more cleaning objectives are selected. The two or more cleaning objectives can comprise least two of: (1) complete wetting of the surface of the substrate, (2) minimum amount of treatment liquid used, (3) a target temperature profile of treatment liquid from center to edge of the substrate, (4) total cleaning time, and the like. In operation 812, two or more cleaning operating variables to be optimized for achieving the two or more cleaning objectives are selected. In operation 816, a surface of the substrate is exposed to the treatment liquid comprising a first treatment chemical, the first treatment chemical with a first film thickness, a first temperature, the first total flow rate, and a first composition, and concurrently irradiating a portion of a surface of the substrate with UV light, the UV light having a wavelength and having a UV power, the irradiating operationally configured to be completed in a first process time, the irradiating performed while the substrate is in a first rotation speed.

In operation 820, the substrate is exposed to a second treatment liquid, the second treatment chemical having a second temperature, the second flow rate, and a second composition, a second process time, and second rotations speed. In operation, 824, the selected plurality of cleaning operating variables are controlled in order to achieve the two or more cleaning objectives. In operation 828, optionally recycling the first and second treatment chemicals so as to reduce treatment liquid usage. In operation 832, if the two or more cleaning objectives are not met, adjusting one or more of cleaning operating variables in order to meet the two or more cleaning objectives.

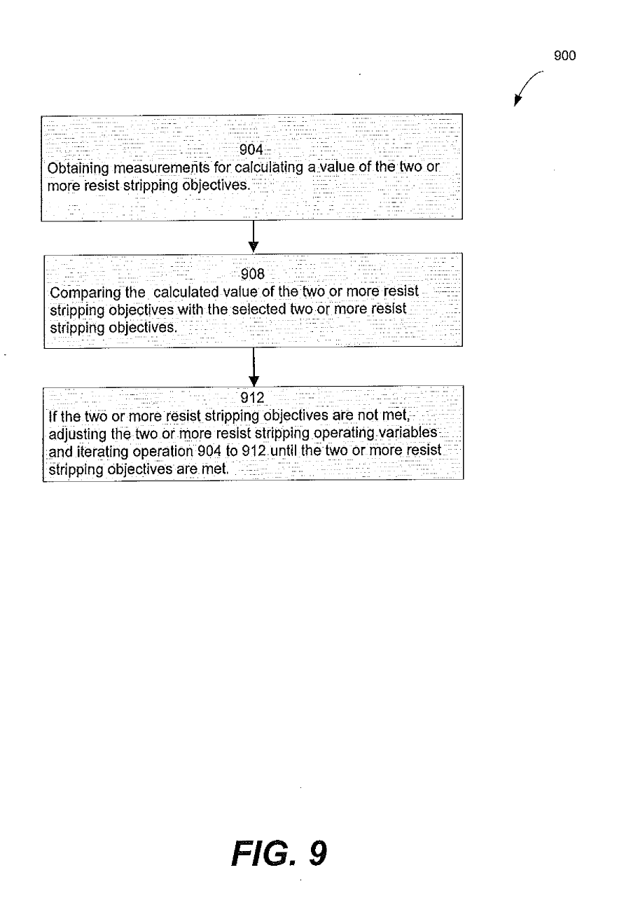

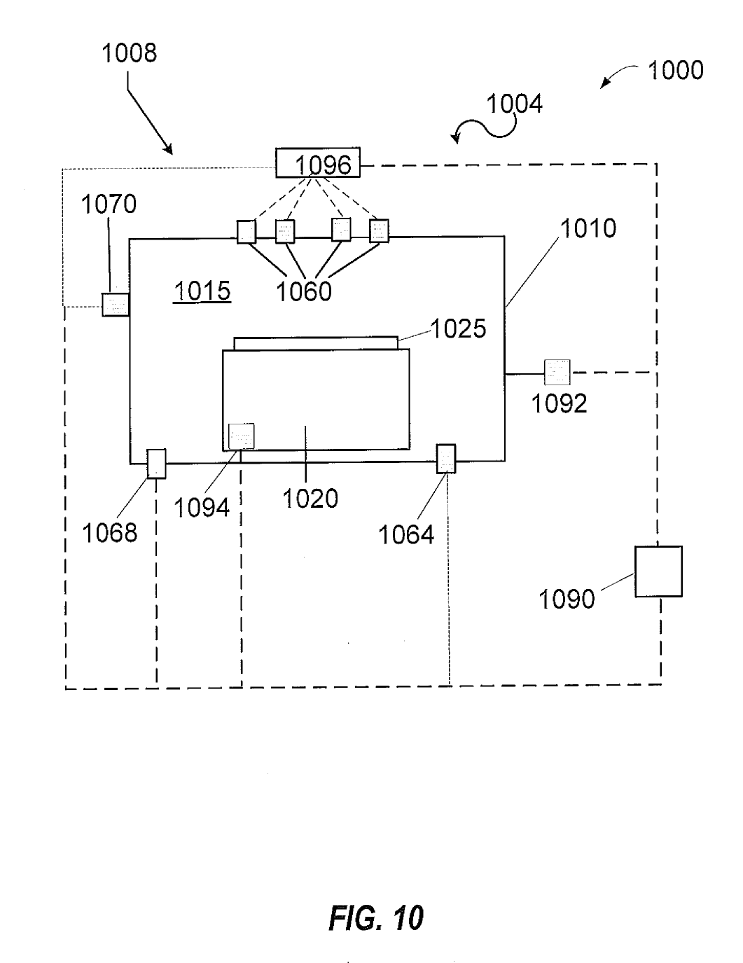

FIG. 9 is an exemplary flowchart 900 of adjusting one or more treatment operating variables to meet the two or more objectives of the present invention. In operation 904, measurements for calculating a value of the two or more cleaning objectives. As will be discussed in relation to FIG. 10, optical metrology devices, such as reflectometer or interferometer used to obtain a film thickness of the treatment liquid above a surface of the substrate and/or process metrology devices are used to obtain other measurements. In operation 908, the calculated value of the two or more cleaning objectives with the selected two or more cleaning objectives. In operation 912, if the two or more cleaning objectives are not met, adjusting the two or more cleaning operating variables and iterating operation 904 to 912 until the two or more cleaning objectives are met.

FIG. 10 is an exemplary architectural diagram 1000 of a cleaning system 1004 depicting use of a controller 1090 for optimizing the operating variables of the cleaning system 1004 towards meeting the one or more pre-treatment objectives. The controller 1090 includes storage and memory configured to store and access recipes for cleaning processes including photoresist stripping, post etch cleaning, film etching involving oxide, nitride or metal, particle removal, metal removal, organic material removal, or photoresist developing. In addition, the controller includes storage to store and access the two or more cleaning objectives, wherein the two or more cleaning objectives further include a process completion percentage and cost per unit throughput or a process completion percentage and cost of ownership per unit of throughput or a total cleaning time.

The controller 1090 can include computer capabilities a) to obtain metrology measurements and/or process measurements used to calculate a value for the selected one or more cleaning objectives, b) if the one or more cleaning objectives are not met, to adjust the process operating variables including adjusting the flow rate of the selected two or more dispense devices, rotation speed of the substrate, duty cycle of each of the selected two or more dispense devices until the one or more cleaning objectives are met. Moreover, the controller 1090 also contains logic circuitry or computer code to concurrently optimize a selected flow rate, dispense flow type, position of a dispense device, height of dispense, and duty cycle for turning on or turning off each of the selected two or more dispense devices, pattern used in positioning the selected two or more dispense devices, and rotation speed of the substrate. Operating data obtained from optimization tests are incorporated into procedures and recipes for combinations of substrate cleaning processes and cleaning operating variables are loaded into the controller 1090. The cleaning system is configured to run in either online mode with metrology feedback or offline mode that does not require continuous metrology feedback, instead using the procedures and recipes.

The cleaning system 1004 can use two or more optical metrology devices 1008. An optical emission spectroscopy (OES) device 1070 can be coupled to the processing chamber 1010 at a position to measure the optical emission from the processing region 1015. In addition, another set of optical metrology devices 1060 can be disposed atop the processing chamber 1010. Although four optical metrology devices are shown, many other alternative and different configurations of the optical metrology devices can be positioned to implement design objectives using a plurality of optical metrology devices. The four optical metrology devices can be spectroscopic reflectometric devices and/or interferometric devices. The measurements from the two or more optical metrology devices, for example, the OES device 1070 and the set of optical metrology devices 1060, are transmitted to the metrology processor (not shown) where one or more critical dimension values are extracted. Measurements can be performed with the one or more optical metrology device OES 1070 and/or the set of optical metrology devices 1060 and one or more etch sensor devices, 1064 and 1068.

As mentioned above, a process sensor device, for example, can be a residue sensor device 1064 measuring the percentage of residue remaining, or measuring a cleaning operating variable with a substantial correlation to percentage of residue removal. Another process sensor device can include a device measuring the partial pressure of oxygen or the oxygen and ozone partial pressures or the total pressure of the process gas. Selection of at least one or more process sensor devices can be done using multivariate analysis using sets of process data, metrology data (diffraction signals) and process performance data to identify these inter-relationships. The measurements from the two or more optical metrology devices, for example, the OES device 1070 and the set of optical metrology devices 1060 and the measurement from the sensor device 1064 and/or 1068 are transmitted to the metrology processor (not shown) where the operating variable values are extracted. Another process sensor device is a temperature measurement device that is used to the temperature of the treatment liquid along the radial line in order to determine the temperature gradient of the treatment liquid from the center to an edge of the substrate. The controller can compare the measured temperature gradient to the set temperature gradient for the application and adjust one or more of the cleaning operating variables to get the temperature to the acceptable range.

Still referring to FIG. 10, the cleaning system 1004 includes a controller 1090 coupled to sub-controllers in the two or more optical metrology measurement devices 1009 comprising a plurality of optical metrology devices 1060, optical emission spectroscopy (OES) device 1070, and one or more etch sensor devices, 1064 and 1068. One or more chemical monitors 1092 can be coupled to the processing chamber to ensure the process gas is within the ranges set. Another sub-controller 1094 can be included in the motion control system 1020 that is coupled to the controller 1090 and can adjust the first and second speed of the rotation of the motion control system for a single substrate tool. The motion control system 1020 is configured to handle substrates from 150 to 450 mm or greater than 150 mm. The controller 1090 can be connected to an intranet or via the Internet to other controllers in order to optimize the cleaning operating variables and in order to achieve the one or more pre-treatment objectives.

Although only certain embodiments of this invention have been described in detail above, those skilled in the art will readily appreciate that many modifications are possible in the embodiments without materially departing from the novel teachings and advantages of this invention. For example, although one exemplary process flow is provided for cleaning of substrates, other process flows are contemplated. As also mentioned above, the cleaning method and system of the present invention can be used in an FEOL or BEOL fabrication cluster. Accordingly, all such modifications are intended to be included within the scope of this invention.a

What is claimed:

1. A system for cleaning a layer on a substrate using a cleaning system, the system comprising:
a cleaning system comprising:
a processing chamber configured to hold a substrate having a surface on a layer comprising an ion implanted resist, the implanted resist forming a residue during ion implantation or a substrate after an ashing process;
a first delivery device coupled to the processing chamber and configured to deliver a first treatment chemical to immerse the substrate during a first process time at a first film thickness of the first treatment chemical; the first delivery device comprising two or more nozzles;
a UV light device coupled to the processing chamber and configured to irradiate the surface of the substrate during the first process time with a UV light, the UV light device having a wavelength and a UV power;
a second delivery device coupled to the processing chamber and configured to deliver a second treatment chemical onto the surface of the substrate during a second process time;
a motion control system coupled to the processing chamber and configured to provide the substrate a first rotation speed during the first process time and a second rotation speed during the second process time; and
a controller coupled to the cleaning system and configured to control two or more cleaning operating variables in order to achieve two or more cleaning objectives;
wherein two or more cleaning operating variables are optimized to achieve the two or more cleaning objectives comprising at least two of: (1) complete wetting of the surface of the substrate, (2) minimum amount of treatment liquid used, and (3) a target temperature profile of treatment liquid from center to edge of the substrate.

2. The system of claim 1 further comprising an optional recycle subsystem coupled to the processing chamber and configured to recycle the first and/or second treatment chemicals.

3. The system of claim 1 wherein the substrate cleaning process include means for performing a standard clean 1 (SC 1), a standard clean 2 (SC 2), water cleaning, or solvent cleaning and/or wherein the substrate cleaning process performed includes a treatment liquid comprising hydrofluoric acid (HF), diluted HF, or buffered HF; or the substrate cleaning process includes a treatment liquid comprising deionized water, isopropyl alcohol, deionized water and ozone, rinsing fluids, sulfuric acid peroxide mixture (SPM), sulfuric acid peroxide and ozone mixture (SOM), phosphoric acid, or phosphoric acid and steam mixture.

4. The system of claim 1 wherein the controller includes means for storing and accessing recipes for cleaning processes including photoresist stripping, post etch cleaning, film etching involving oxide, nitride or metal, particle removal, metal removal, organic material removal, or photoresist developing.

5. The system of claim 1 wherein the motion control system is configured to handle substrates from 150 to 450 mm or greater than 150 mm.

6. The system of claim 1 wherein the controller includes storage to store and access the two or more target cleaning objectives, wherein the two or more cleaning objectives further include a target process completion percentage and target cost per unit throughput or a target process completion percentage and target cost of ownership per unit of throughput or a total cleaning time.

7. The system of claim 1 wherein the selected two or more dispense devices have varying sizes of dispense width.

8. The system of claim 7 wherein the selected two or more dispense devices comprise a central nozzle and one or more additional nozzles located at selected distances from the central nozzle towards an edge of the substrate, the central nozzle configured with a flow rate lower than any of the one or more additional nozzles.

9. The system of claim 8 wherein cleaning system further comprises metrology devices configured to measure wetting of the substrate with the treatment liquid.

10. The system of claim 10 wherein the first delivery device is configured to support a treatment liquid flow rate in a range from 15 to 500 mL/min, 15 mL/min, or less than 15 mL/min.

11. The system of claim 10 wherein the dispense width is of sufficient size to allow a continuous dispense of the treatment liquid at the selected flow rate of the dispense device.

12. The system of claim 1 wherein the selected two or more dispense devices are positioned above the substrate according to a selected pattern, the selected pattern including a height from the substrate surface to the dispense device and distance between a central dispense device and each additional dispense device of the selected two or more dispense devices.

13. The system of claim 12 wherein the controller includes computer capabilities a) to obtain metrology measurements and/or process measurements used to calculate a value for the selected one or more target cleaning objectives, b) if the one or more target cleaning objectives are not met, to adjust the process operating variables including adjusting the flow rate of the selected two or more dispense devices, rotation speed of the substrate, duty cycle of each of the selected two or more dispense devices until the one or more target cleaning objectives are met.

14. The system of claim 13 wherein the cleaning system includes a temperature measurement device to determine temperature gradient of the treatment liquid from the substrate center to an edge of the substrate.

15. The system of claim 14 wherein the cleaning system further includes a reflectometer or interferometer used to obtain an film thickness of the treatment liquid above a surface of the substrate.

16. The system of claim 15 wherein the selected two or more dispense devices comprising of nozzles are connected to a single supply line and the duty cycle requires sequential turning on and turning off from a central nozzle towards a nozzle closest to the edge of the substrate and from the nozzle closest to the edge of the substrate towards the central nozzle.

17. The system of claim 16 wherein each dispense device of the selected two or more dispense devices are independently connected to a supply line and can be turned on and turned off independently; and/or wherein the selected two or more dispense devices are disposed in a line pattern, a cross pattern, a 3-ray star pattern configuration; and/or wherein the selected two or more dispense devices can be turned on and turned off independently.

18. The system of claim 17 wherein the controller contains logic circuitry or computer code to concurrently optimize a selected flow rate, dispense flow type, position of a dispense device, height of dispense, and duty cycle for turning on or turning off each of the selected two or more dispense devices, pattern used in positioning the selected two or more dispense devices, and rotation speed of the substrate.

19. The system of claim 18 wherein operating data obtained from optimization tests are incorporated into procedures and recipes for combinations of substrate cleaning processes and cleaning operating variables wherein the operating data are loaded into the controller and the cleaning system is configured to run in either online mode with metrology feedback or offline mode that does not require continuous metrology feedback, instead using the procedures and recipes.

20. The system of claim 1 wherein the treatment liquid is a sulfuric acid peroxide mixture (SPM) or sulfuric acid peroxide and ozone mixture (SOM), the substrate cleaning process is photoresist stripping, the flow rate of the SPM is 2 liters per minute or less, the selected two or more dispense devices comprise 5 nozzles, including a central nozzle and 4 additional nozzles, arranged in a line pattern, and the substrate is from 200 to 450 mm.
